(19) United States
(12) Patent Application Publication
(10) Pub. No.: US 2008/0179044 A1
(43) Pub. Date: Jul. 31, 2008

(54) Heat dissipating device

(75) Inventors: Jen-Lu Hu, Tainan City (TW); Hao-Hui Lin, Taitung City (TW); Tsung-Ching Lin, Tainan City (TW)

Correspondence Address: DLA PIPER US LLP, 2000 UNIVERSITY AVENUE, E. PALO ALTO, CA, 94303-2248, US

(73) Assignee: Man Zai Industrial Co., Ltd.

(21) Appl. No.: 11/701,201

(22) Filed: Jan. 31, 2007

(51) Int. Cl. H05K 7/20

(52) U.S. Cl. 165/80.4; 361/699

(57) ABSTRACT

A heat dissipating device includes: a heat sink including a casing having upper and lower chambers, the casing being formed with a fluid inlet in fluid communication with the upper chamber, and a fin unit provided in the lower chamber; a pump mounted on the casing for withdrawing fluid from the lower chamber; and an external cooling unit including a radiator mounted on the casing and including first and second side tanks, conduits connected to the first and second side tanks, and a fin structure connected to the first and second side tanks and the conduits. The first side tank is in fluid communication with the pump. The second side tank is in fluid communication with the fluid inlet of the casing. A cooling fan faces toward the fin structure of the radiator.

### BACKGROUND OF THE INVENTION

1. Field of the Invention

The invention relates to a heat dissipating device, more particularly to a heat dissipating device having a liquid cooled heat sink with a pump mounted thereon.

2. Description of the Related Art

As shown in FIG. 1, a conventional heat dissipating device 1 generally includes a radiator 12 having a fluid inlet 122 and a fluid outlet 121, a heat sink 11 having a coolant inlet 111 and a coolant outlet 112, an inlet conduit 13, an outlet conduit 14, and a pump 15. The heat sink 11 is adapted to be connected to a heat source (not shown), such as a CPU or a heat-generating electronic component of a display. The outlet conduit 14 interconnects the coolant outlet 112 of the heat sink 11 and the fluid inlet 122 of the radiator 12. The pump 15 is mounted on the inlet conduit 13, and the inlet conduit 13 has a first conduit section 131 interconnecting the fluid outlet 121 of the radiator 12 and the pump 15, and a second conduit section 132 interconnecting the pump 15 and the coolant inlet 111 of the heat sink 11.

When the pump 15 is operated, a coolant is driven to circulate through the heat sink 11, the outlet conduit 14, the radiator 12, and the inlet conduit 13, and carries heat absorbed by the heat sink 11 to the radiator 12 so as to dissipate heat thereat.

Although the conventional heat dissipating device 1 has the heat dissipating effect, there are still some disadvantages:

1) An undesired high coolant vaporizing rate due to connection between the pump 15 and the first and second conduit sections 131, 132 of the inlet conduit 13 occurs.

2) A larger space is required to accommodate the pump 15 and the first and second conduit sections 131, 132 of the inlet conduit 13.

3) Assembly of the pump 15 and the first and second conduit sections 131, 132 of the inlet conduit 13 is inconvenient when the space for accommodating the heat dissipating device 1 is small.

### SUMMARY OF THE INVENTION

Therefore, the object of the present invention is to provide a heat dissipating device that can overcome the aforesaid disadvantages associated with the prior art.

Accordingly, a heat dissipating device of the present invention is adapted to be connected to an electronic component and comprises: a heat sink including a casing defining an inner space and provided with a partitioning wall that divides the inner space into upper and lower chambers, the partitioning wall being formed with a fluid passage in fluid communication with the upper and lower chambers, the casing being formed with a fluid inlet that is in fluid communication with the upper chamber, and a fin unit provided in the lower chamber; a pump mounted directly on the casing and having a suction end in fluid communication with the lower chamber for withdrawing fluid from the lower chamber, and a discharging end; and an external cooling unit including a radiator mounted on the casing and including first and second side tanks, a plurality of conduits interconnecting and in fluid communication with the first and second side tanks, and a fin structure disposed between the first and second side tanks and connected to the first and second side tanks and the conduits.

The first side tank is in fluid communication with the discharging end of the pump. The second side tank is in fluid communication with the fluid inlet of the casing so as to permit fluid circulation through the heat sink and the radiator. The external cooling unit further includes a cooling fan facing toward the fin structure of the radiator.

### BRIEF DESCRIPTION OF THE DRAWINGS

Other features and advantages of the present invention will become apparent in the following detailed description of the preferred embodiments with reference to the accompanying drawings, of which:

FIG. 1 is a schematic view of a conventional heat dissipating device;

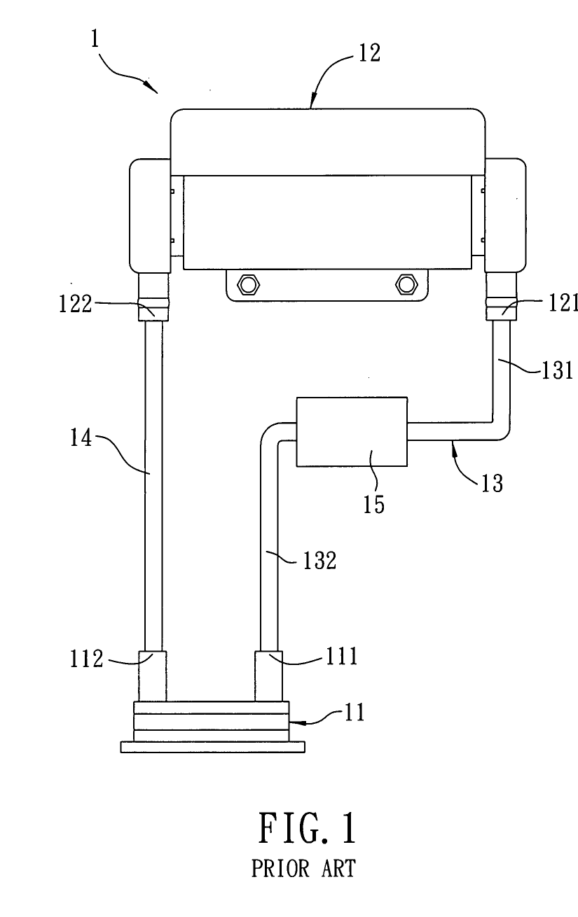

FIG. 2 is a perspective view of the first preferred embodiment of a heat dissipating device according to the present invention;

FIG. 3 is a schematic partly sectional view of the first preferred embodiment;

FIG. 4 is a schematic partly sectional view of the second preferred embodiment of a heat dissipating device according to the present invention; and

FIG. 5 is a schematic partly sectional view of the third preferred embodiment of a heat dissipating device according to the present invention.

### DETAILED DESCRIPTION OF THE PREFERRED EMBODIMENTS

Before the present invention is described in greater detail with reference to the accompanying preferred embodiments, it should be noted herein that like elements are denoted by the same reference numerals throughout the disclosure.

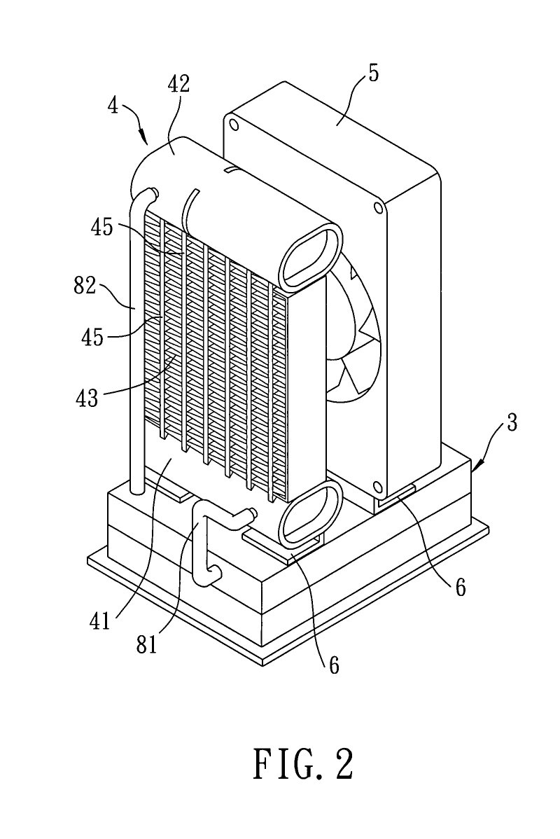

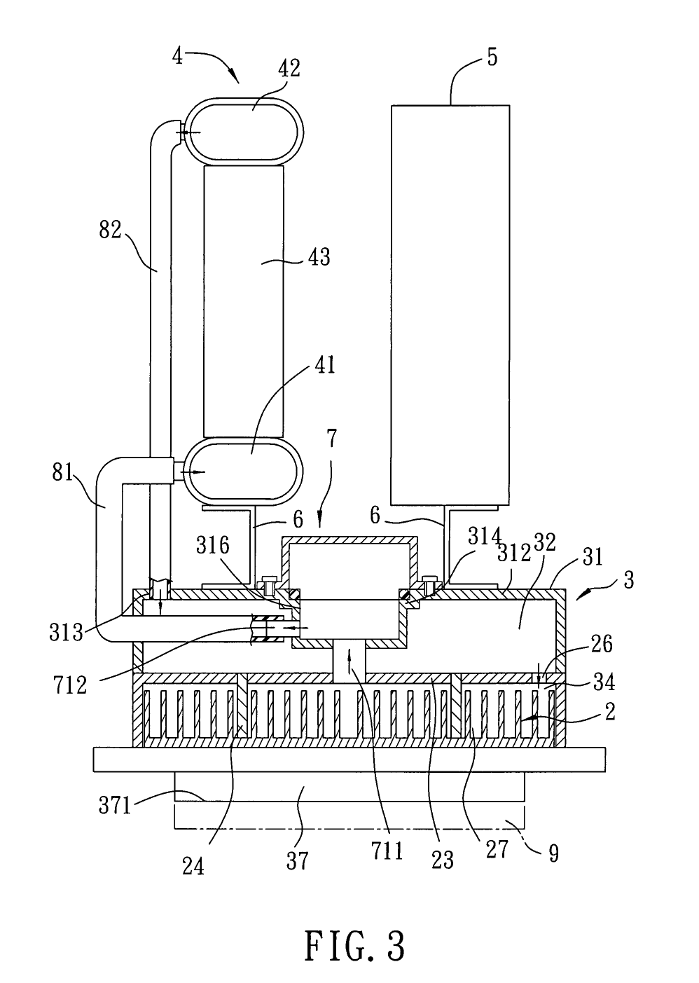

Referring to FIGS. 2 and 3, the first preferred embodiment of a heat dissipating device according to the present invention is shown to be adapted to be connected to an electronic component 9 for dissipating heat generated by the electronic component 9.

The heat dissipating device includes: a heat sink 3 including a casing 31 defining an inner space and provided with a partitioning wall 23 that divides the inner space into upper and lower chambers 32, 34, the partitioning wall 23 being formed with a fluid passage 26 in fluid communication with the upper and lower chambers 32, 30, the casing 31 being formed with a fluid inlet 313 that is in fluid communication with the upper chamber 32, and a fin unit 2 provided in the lower chamber 34; a pump 7 mounted directly on the casing 31 and having a suction end 711 in fluid communication with the lower chamber 34 for withdrawing fluid from the lower chamber 34, and a discharging end 712; and an external cooling unit including a radiator 4 that is mounted on the casing 31 and that has first and second side tanks 41, 42, a plurality of conduits 45 interconnecting and in fluid communication with the first and second side tanks 41, 42, and a fin structure 43 disposed between the first and second side tanks 41, 42 and connected to the first and second side tanks 41, 42 and the conduits 45. The first side tank 41 is in fluid communication with the discharging end 712 of the pump 7. The second side tank 42 is in fluid communication with the fluid inlet 313 of the casing 31 so as to permit fluid circulation through the heat sink 3 and the radiator 4. The external cooling unit further includes a cooling fan 5 facing toward the fin structure 43 of the radiator 4.

In this embodiment, the suction end 711 of the pump 7 is disposed in the upper chamber 32 and extends through the partitioning wall 23 so as to be in fluid communication with the lower chamber 34. The discharging end 712 of the pump 7 is disposed in the upper chamber 32. The heat dissipating device further includes a first connecting pipe 81 interconnecting and in fluid communication with the discharging end 712 of the pump 7 and the first side tank 41, and a second connecting pipe 82 interconnecting and in fluid communication with the second side tank 42 and the fluid inlet 313 of the casing 31.

Preferably, the casing 31 is provided with spacers 6 so that the radiator 4 and the cooling fan 5 are respectively and securely supported on the spacers 6. The casing 31 has a bottom formed with an attaching protrusion 37 that has a planar surface 371 adapted to be attached to the electronic component 9. In this preferred embodiment, the radiator 4 and the cooling fan 5 are disposed in an upright manner such that the fin structure 43 of the radiator 4 and the cooling fan 5 face in a horizontal direction parallel to the planar surface 371 of the attaching protrusion 37. It should be mentioned herein that the spacers 6 are not essential components of this invention, and that the radiator 4 and the cooling fan 5 can be mounted directly on the casing 31.

The radiator 4 and the casing 31 are made from a metal material with good heat conductivity. The partitioning wall 23 and the casing 31 can be integrally formed or connected to each other using welding techniques. The casing 31 has a top wall 312 that is formed with the fluid inlet 313, and a recess 316 defined by a recess-defining wall 314. The pump 7 is mounted on the top wall 312 and extends into the recess 316. The suction end 711 of the pump 7 extends through the recess-defining wall 314 into the lower chamber 34.

The casing 31 further includes a plurality of dividing walls 24 extending between the partitioning wall 23 and the bottom of the casing 31 so as to form the lower chamber 34 into a tortuous fluid path 27.

Since the pump 7 is well-known in the art, no further details are provided for the sake of brevity.

Before use, the fluid (i.e., the coolant) is filled in the first and second side tanks 41, 42, the conduits 45, the first connecting pipe 81, the second connecting pipe 82, and the casing 31. In use, the pump 7 is started, so that the coolant in the radiator 4 of the external cooling unit is pumped through the second connecting pipe 82 into the heat sink 3 for heat exchange with the high-temperature electronic component 9. Thereafter, the heated coolant flows in sequence through the first connecting pipe 81, the first side tank 41, the conduits 45, and the second side tank 42. As the coolant flows through the conduits 45, the fin structure 43 absorbs heat and is cooled by the cooling fan 5.

By mounting the pump 7 directly on the casing 31 of the heat dissipating device of this invention, the aforesaid drawbacks associated with the prior art can be eliminated.

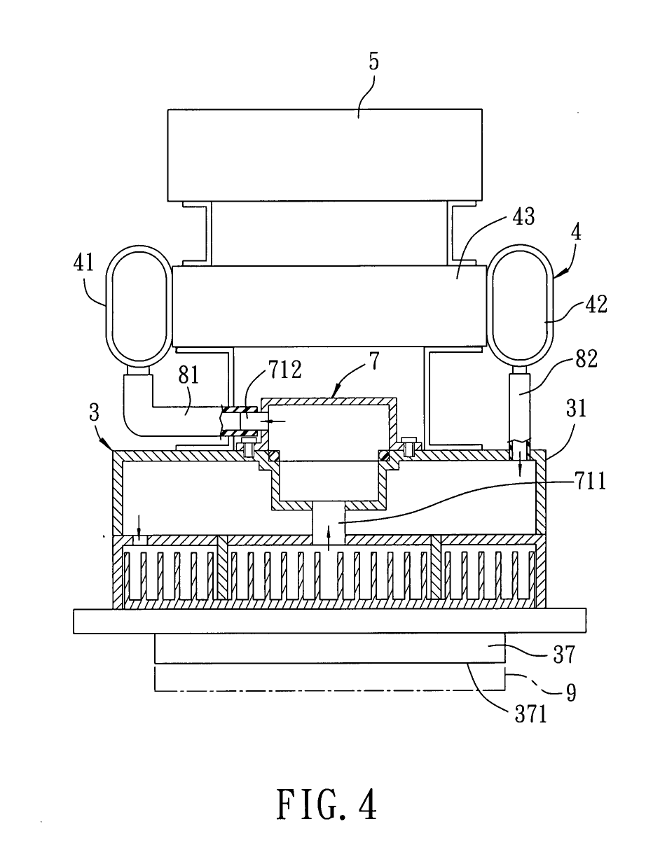

As shown in FIG. 4, the second preferred embodiment of this invention differs from the previous embodiment in that the radiator 4 and the cooling fan 5 are disposed in a horizontal manner such that the fin structure 43 of the radiator 4 and the cooling fan 5 face in a normal direction normal to the planar surface 371 of the attaching protrusion 37 and that the cooling fan 5 is stacked on the radiator 4. In this embodiment, the discharging end 712 of the pump 7 is disposed outwardly of the casing 31.

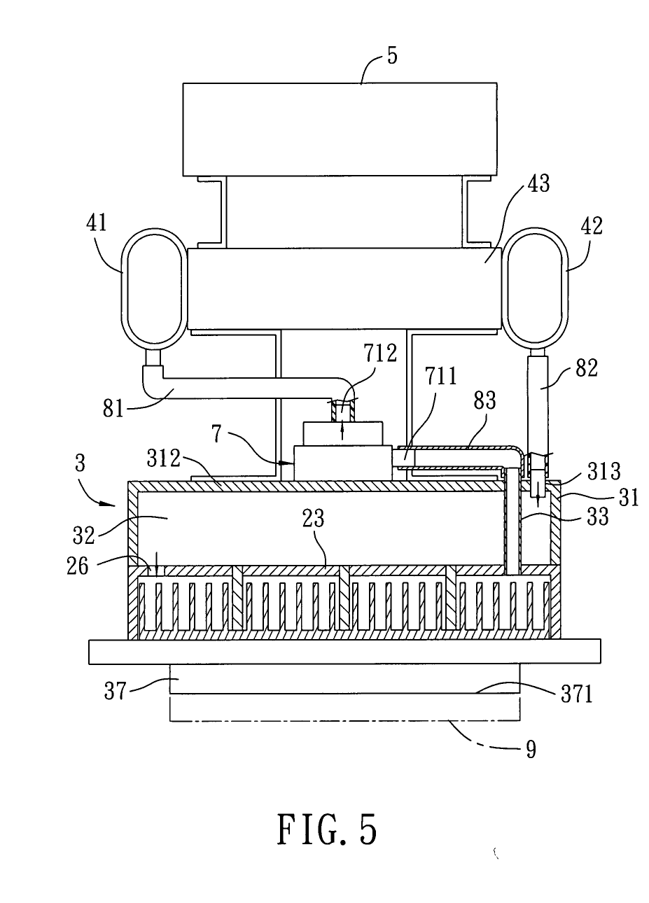

As shown in FIG. 5, the third preferred embodiment of this invention differs from the previous embodiments in that the suction end 711 and the discharging end 712 of the pump 7 are disposed outwardly of the casing 31 and that the heat dissipating device further includes a connecting tube 33 extending through the upper chamber 32 and the partitioning wall 23 so as to be in fluid communication with the lower chamber 34, and a third connecting pipe 83 interconnecting and in fluid communication with the suction end 711 of the pump 7 and the connecting tube 33.

While the present invention has been described in connection with what are considered the most practical and preferred embodiments, it is understood that this invention is not limited to the disclosed embodiments but is intended to cover various arrangements included within the spirit and scope of the broadest interpretation so as to encompass all such modifications and equivalent arrangements.

What is claimed is:

1. A heat dissipating device adapted to be connected to an electronic component, said heat dissipating device comprising:
a heat sink including
a casing defining an inner space and provided with a partitioning wall that divides said inner space into upper and lower chambers, said partitioning wall being formed with a fluid passage in fluid communication with said upper and lower chambers, said casing being formed with a fluid inlet that is in fluid communication with said upper chamber, and
a fin unit provided in said lower chamber;
a pump mounted directly on said casing and having a suction end in fluid communication with said lower chamber for withdrawing fluid from said lower chamber, and a discharging end; and
an external cooling unit including
a radiator mounted on said casing and including first and second side tanks, a plurality of conduits interconnecting and in fluid communication with said first and second side tanks, and a fin structure disposed between said first and second side tanks and connected to said first and second side tanks and said conduits, said first side tank being in fluid communication with said discharging end of said pump, said second side tank being in fluid communication with said fluid inlet of said casing so as to permit fluid circulation through said heat sink and said radiator, and
a cooling fan facing toward said fin structure of said radiator.

2. The heat dissipating device as claimed in claim 1, wherein said suction end of said pump is disposed in said upper chamber and extends through said partitioning wall so as to be in fluid communication with said lower chamber, said discharging end of said pump being disposed in said upper chamber, said heat dissipating device further comprising a first connecting pipe interconnecting and in fluid communication with said discharging end of said pump and said first side tank, and a second connecting pipe interconnecting and in fluid communication with said second side tank and said fluid inlet of said casing.

3. The heat dissipating device as claimed in claim 1, wherein said casing is provided with spacers, said radiator and said cooling fan being respectively and securely supported on said spacers.

4. The heat dissipating device as claimed in claim 2, wherein said casing has a bottom formed with an attaching protrusion that has a planar surface adapted to be attached to the electronic component, said radiator and said cooling fan being disposed in an upright manner such that said fin structure of said radiator and said cooling fan face in a horizontal direction parallel to said planar surface of said attaching protrusion.

5. The heat dissipating device as claimed in claim 1, wherein said suction end of said pump is disposed in said upper chamber and extends through said partitioning wall so as to be in fluid communication with said lower chamber, said discharging end of said pump being disposed outwardly of said casing, said heat dissipating device further comprising a first connecting pipe interconnecting and in fluid communication with said discharging end of said pump and said first side tank, and a second connecting pipe interconnecting and in fluid communication with said second side tank and said fluid inlet of said casing.

6. The heat dissipating device as claimed in claim 5, wherein said casing has a bottom formed with an attaching protrusion that has a planar surface adapted to be attached to the electronic component, said radiator and said cooling fan being disposed in a horizontal manner such that said fin structure of said radiator and said cooling fan face in a normal direction normal to said planar surface of said attaching protrusion, said cooling fan being stacked on said radiator.

7. The heat dissipating device as claimed in claim 1, wherein said suction end and said discharging end of said pump are disposed outwardly of said casing, said heat dissipating device further comprising a connecting tube extending through said upper chamber and said partitioning wall so as to be in fluid communication with said lower chamber, a first connecting pipe interconnecting and in fluid communication with said discharging end of said pump and said first side tank, a second connecting pipe interconnecting and in fluid communication with said second side tank and said fluid inlet of said casing, and a third connecting pipe interconnecting and in fluid communication with said suction end of said pump and said connecting tube.

8. The heat dissipating device as claimed in claim 7, wherein said casing has a bottom formed with an attaching protrusion that has a planar surface adapted to be attached to the electronic component, said radiator and said cooling fan being disposed in a horizontal manner such that said fin structure of said radiator and said cooling fan face in a normal direction normal to said planar surface of said attaching protrusion, said cooling fan being stacked on said radiator.
